(19) United States
(12) Patent Application Publication
(10) Pub. No.: US 2024/0114641 A1
(43) Pub. Date: Apr. 4, 2024

(54) ELECTRONIC DEVICE HAVING ANODIZED HOUSING AND METHOD OF PRODUCING THE SAME

(71) Applicant: Samsung Electronics Co., Ltd., Suwon-si (KR)

(72) Inventors: Byounghee CHOI, Suwon-si (KR); Giwon SEOL, Suwon-si (KR); Sunghwan YOON, Suwon-si (KR); Kangeun LEE, Suwon-si (KR); Jinho LEE, Suwon-si (KR); Doohyeon CHO, Suwon-si (KR); Youngsoo HA, Suwon-si (KR)

(21) Appl. No.: 18/516,224

(22) Filed: Nov. 21, 2023

Related U.S. Application Data
(63) Continuation of application No. PCT/KR2023/015136, filed on Sep. 27, 2023.

(30) Foreign Application Priority Data
Sep. 29, 2022 (KR) 10-2022-0124564
Nov. 7, 2022 (KR) 10-2022-0147097
Sep. 11, 2023 (KR) 10-2023-0120520

(51) Int. Cl. H05K 5/04; C25D 11/08; C25D 11/12; C25D 11/24

(52) U.S. Cl. CPC H05K 5/04; C25D 11/08; C25D 11/12; C25D 11/246

(57) ABSTRACT

A housing of an electronic device is disclosed. A housing of an electronic device according to various embodiments of the disclosure may include: a base material containing an aluminum alloy material; a barrier layer formed by anodizing the aluminum of the base material on a surface facing a first direction of the base material, the barrier layer having a thickness of 50 to 150 nanometers; a first porous film located in the first direction with respect to the barrier layer; and a second porous film formed between the first porous film and the barrier layer.

### CROSS-REFERENCE TO RELATED APPLICATIONS

This application is a continuation of International Application No. PCT/KR2023/015136 designating the United States, filed on Sep. 27, 2023, in the Korean Intellectual Property Receiving Office and claiming priority to Korean Patent Application Nos. 10-2022-0124564, filed on Sep. 29, 2022, 10-2022-0147097, filed on Nov. 7, 2022, and 10-2023-0120520, filed on Sep. 11, 2023, in the Korean Intellectual Property Office, the disclosures of all of which are incorporated by reference herein in their entireties.

### BACKGROUND

### Field

The disclosure relates to a housing of an electronic device and, for example, an electronic device having an anodized housing and a method of manufacturing the same.

### Description of Related Art

A housing of an electronic device may be formed of a material such as metal, glass, plastic, or a combination thereof. Among the above-described materials, a metal material has high strength and impact toughness and is thus widely used as a housing for an electronic device. For example, aluminum and/or an alloy containing the same has a low density, is capable of obtaining high strength by age hardening, and is thus suitable for a housing of an electronic device. Since metal is vulnerable to corrosion, a passivation film (passivation layer) may be generally formed on the surface of the metal to reduce corrosion and improve appearance quality.

Aluminum and/or an alloy containing the same may be generally oxidized in air, and thus a passivation film may be naturally formed. Such a native oxide film may have insufficient thickness and thus have low protection performance for a base material in harsh chemical and/or physical environments. Therefore, in order to form a thick passivation film on the surface of the base material compared to the native oxide film, an anodizing process which electrochemically oxidizes the surface of a base material by passing electricity via the base material as an anode in an electrolyte is widely used.

7000 series aluminum alloys (e.g., alloys such as 7005, 7039, and 7075), which are aluminum alloys containing zinc and magnesium as main alloying elements, may have low adhesion to an anodized layer manufactured by a conventional anodizing process, and thus surface defects and corrosion due to the removal of the anodized layer may occur.

When the growth rate of an anodized layer is slow, the thickness of a barrier layer at the bottom of the anodized layer may be thin, making it difficult to block propagation of cracks caused by stress, and may thus cause the anodized layer to fall off due to cracks. In addition, when the growth rate of an anodized layer is fast, excessive segregation of the anodizing solute in the anodic oxide layer and a base material may decrease the adhesion between the anodized layer and the base material, thereby causing the anodized layer to fall off.

### SUMMARY

Embodiments of the disclosure may provide an electronic device including a housing which has an anodized layer having improved resistance to cracking and adhesion to a base material.

Embodiments of the disclosure may provide a method of manufacturing an electronic device including a housing having the above-described characteristics.

An electronic device according to various example embodiments of the disclosure may comprise: a housing, wherein the housing includes a base material comprising an aluminum alloy material, an anodized barrier layer comprising an anodized aluminum base material on a surface facing a first direction of the base material, the barrier layer having a thickness of 10 to 150 nanometers, a first porous film located in the first direction with respect to the barrier layer, and a second porous film formed between the first porous film and the barrier layer.

In various example embodiments, the thickness of the second porous film may be 1000 to 20000 nanometers.

In various example embodiments, the first porous film may include a first void, and the second porous film may include a second void. A diameter of the second void may be greater than a diameter of the first void.

In various example embodiments, the barrier layer may include at least one of chromium or sulfur.

In various example embodiments, the electronic device may include a sealing layer formed on a surface facing the first direction of the first porous film. In various example embodiments, the thickness of the sealing layer may be 60 to 120 nanometers. In various example embodiments, the sealing layer may include nickel and fluorine.

In various example embodiments, the sum of the contents of nickel and fluorine in the sealing layer may be 15 to 20% by weight. In various example embodiments, the weight ratio of nickel and fluorine in the sealing layer may be 3:2 to 2:1.

A method of manufacturing a housing for an electronic device according to various example embodiments of the disclosure may include: a first anodizing operation including immersing a base material in an anodizing solution and applying a first voltage to form a first porous film on the surface of the base material, and a second anodizing operation including applying a second voltage to the base material on which the first anodizing operation has been performed in an anodizing solution to form a second porous film and a barrier layer on the surface between the base material and the first porous film. The second voltage may be higher than the first voltage.

In various example embodiments, the second anodizing operation may be performed for 60 to 6000 seconds.

In various example embodiments, the second anodizing operation may be performed in a state of being immersed in a solution containing at least one of chromic acid or sulfuric acid.

In various example embodiments, the manufacturing method may further include a sealing operation, performed after the second anodizing operation, comprising immersing the base material in a sealing solution to form a sealing layer. In various example embodiments, the sealing solution may contain nickel and fluorine. In various example embodiments, the sealing operation may be performed for 20 to 50 minutes. In various example embodiments, in the sealing operation the sum of nickel and fluorine contents of the sealing layer is 15 to 20% by weight.

In various example embodiments, in the sealing operation the ratio of nickel and fluorine contents in the sealing layer is 3:2 to 2:1 based on weight.

A housing of an electronic device according to various example embodiments of the disclosure may be manufactured by a method including: a first anodizing operation including immersing a base material in an anodizing solution and applying a first voltage to form a first porous film on a surface of the base material, and a second anodizing operation including applying a second voltage higher than the first voltage, to the base material on which the first anodizing operation has been performed in an anodizing solution to form a second porous film and a barrier layer on the surface between the base material and the first porous film. In various example embodiments, the housing may be manufactured by a method in which the second anodizing operation is performed for 60 to 6000 seconds. In various example embodiments, the housing may be manufactured by a method performed after the second anodizing operation and including a sealing operation including immersing the base material in a sealing solution containing nickel and fluorine to form a sealing layer on the surface of the first porous film.

According to various example embodiments disclosed herein, a barrier layer formed on a surface of a base material may have the thickness of 10 to 150 nanometers to arrest the propagation of cracks occurring in an anodizing layer, and the voltage applied in a second anodizing operation may be increased compared to a first anodizing operation, thereby improving adhesion between the formed barrier layer and the base material.

### BRIEF DESCRIPTION OF THE DRAWINGS

In relation to the description of the drawings, the same or similar reference numerals may be used for the same or similar elements. Further, the above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2A is a front perspective view of an electronic device according to various embodiments;

FIG. 2B is a rear perspective view of an electronic device according to various embodiments;

FIG. 3 is a cross-sectional view illustrating a surface of a housing of an electronic device according to various embodiments;

FIG. 4A is a flowchart illustrating an example method of manufacturing a housing according to various embodiments;

FIG. 4B is a diagram illustrating an example process for manufacturing a housing according to various embodiments;

FIG. 5A is a graph showing a change in voltage over time in a method of manufacturing a housing according to comparative examples and various embodiments;

FIG. 5B is an electron micrograph showing an anodizing layer and a base material of a housing according to various embodiments;

FIG. 5C is an electron micrograph showing an anodizing layer and a base material of a housing according to a comparative example of the disclosure;

FIG. 5D is an electron micrograph showing an anodizing layer and a base material of a housing according to a comparative example of the disclosure;

FIG. 6A is an electron micrograph showing the result of a crack propagation test with respect to a cross section of an anodizing layer according to various embodiments;

FIG. 6B is an electron micrograph showing the results of a crack propagation test with respect to a cross section and a surface of an anodizing layer according to a comparative example; and

FIGS. 7A, 7B and 7C are electron micrographs showing a surface of a sealing layer according to various embodiments.

### DETAILED DESCRIPTION

Hereinafter, various example embodiments of the disclosure will be described in greater detail with reference to the accompanying drawings. In the drawings, for example, the sizes and shapes of members may be exaggerated for the sake of descriptive convenience and clarity, and when actually implemented, the illustrated shapes may be modified. Therefore, the disclosure should not be construed to be limited to particular shapes of parts described and shown herein.

Throughout the drawings, the same or like reference numerals designate the same or like elements. As used in the disclosure, the term “and/or” includes any one of items enumerated and all combinations of one or more thereof.

Various changes and modification in form may be made to the various example embodiments as described below, and the scope of the disclosure is not limited thereto. Rather, the example embodiments are presented to more fully and completely describe the disclosure and completely transfer the idea of the disclosure to those skilled in the art.

Terms used in the disclosure are used to explain various embodiments, and are not intended to limit the disclosure. Also, a singular expression in the disclosure may include a plural expression unless the singular expression is clearly specified in the context. Furthermore, terms “comprise” and/or “comprising” is intended to specify the existence of mentioned shapes, numbers, steps, members, elements, and/or groups thereof, and is not intended to preclude the existence or addition of other shapes, numbers, steps, members, elements, and/or groups thereof.

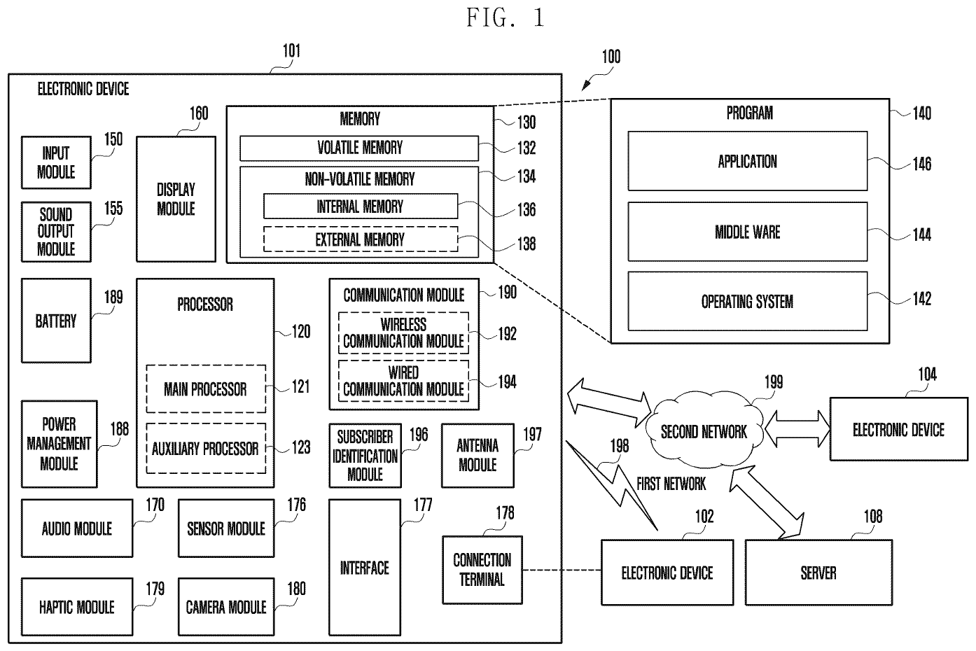

FIG. 1 is a block diagram illustrating an example electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input 1module 150, a sound output 1module 155, a display 1module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display 1module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input 1module 150 may receive a command or data to be used by another component (e.g., the processor 120) of the electronic device 101, from the outside (e.g., a user) of the electronic device 101. The input 1module 150 may include, for example, a microphone, a mouse, a keyboard, a key (e.g., a button), or a digital pen (e.g., a stylus pen).

The sound output 1module 155 may output sound signals to the outside of the electronic device 101. The sound output 1module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display 1module 160 may visually provide information to the outside (e.g., a user) of the electronic device 101. The display 1module 160 may include, for example, a display, a hologram device, or a projector and control circuitry to control a corresponding one of the display, hologram device, and projector. According to an embodiment, the display 1module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input 1module 150, or output the sound via the sound output 1module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments disclosed herein may be one of various types of electronic devices. The electronic devices may include, for example, a portable communication device (e.g., a smart phone), a computer device, a portable multimedia device, a portable medical device, a camera, a wearable device, a home appliance, or the like. The electronic device according to embodiments of the disclosure is not limited to those described above.

It should be appreciated that various embodiments of the disclosure and the terms used therein are not intended to limit the technological features set forth herein to particular embodiments and include various changes, equivalents, or alternatives for a corresponding embodiment. With regard to the description of the drawings, similar reference numerals may be used to designate similar or relevant elements. A singular form of a noun corresponding to an item may include one or more of the items, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “a first”, “a second”, “the first”, and “the second” may be used to simply distinguish a corresponding element from another, and does not limit the elements in other aspect (e.g., importance or order). It is to be understood that if an element (e.g., a first element) is referred to, with or without the term “operatively” or “communicatively”, as “coupled with/to” or “connected with/to” another element (e.g., a second element), the element may be coupled/connected with/to the other element directly (e.g., wiredly), wirelessly, or via a third element.

As used herein, the term “module” may include a unit implemented in hardware, software, or firmware, or any combination thereof, and may be interchangeably used with other terms, for example, “logic,” “logic block,” “component,” or “circuit”. The “module” may be a minimum unit of a single integrated component adapted to perform one or more functions, or a part thereof. For example, according to an embodiment, the “module” may be implemented in the form of an application-specific integrated circuit (ASIC).

Various embodiments as set forth herein may be implemented as software (e.g., the program 140) including one or more instructions that are stored in a storage medium (e.g., the internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each element (e.g., a module or a program) of the above-described elements may include a single entity or multiple entities, and some of the multiple entities may be separately disposed in any other element. According to various embodiments, one or more of the above-described elements may be omitted, or one or more other elements may be added. Alternatively or additionally, a plurality of elements (e.g., modules or programs) may be integrated into a single element. In such a case, according to various embodiments, the integrated element may still perform one or more functions of each of the plurality of elements in the same or similar manner as they are performed by a corresponding one of the plurality of elements before the integration. According to various embodiments, operations performed by the module, the program, or another element may be carried out sequentially, in parallel, repeatedly, or heuristically, or one or more of the operations may be executed in a different order or omitted, or one or more other operations may be added.

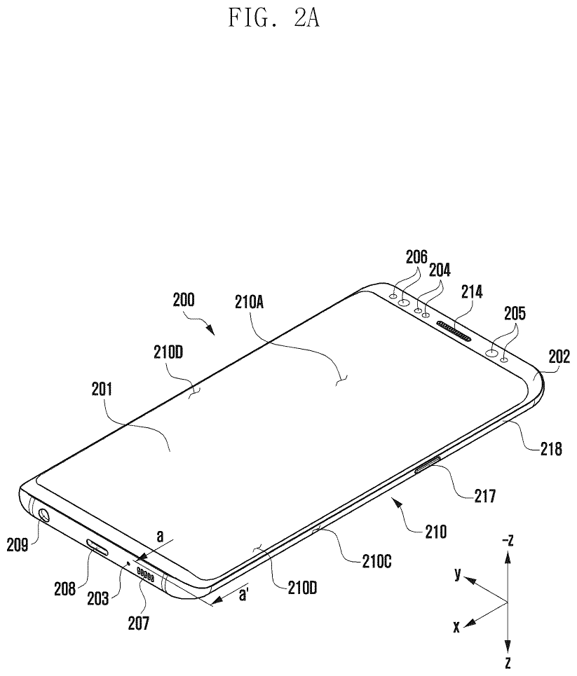

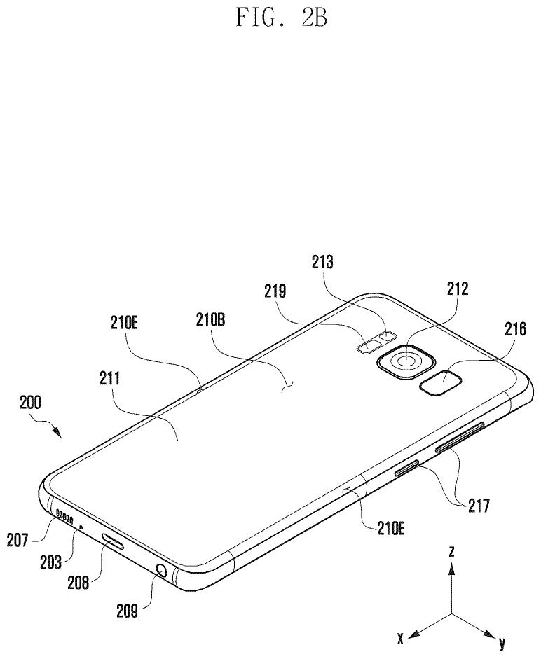

FIG. 2A is a front perspective view of an electronic device according to various embodiments.

FIG. 2B is a rear perspective view of an electronic device according to various embodiments.

Referring to FIGS. 2A and 2B, an electronic device 200 according to an embodiment may include a housing 210 including a first surface (or a front surface) 210A, a second surface (or a rear surface) 210B, and a side surface 210C surrounding a space between the first surface 210A and the second surface 210B. In an embodiment (not shown), the housing may refer to a structure forming a part of the first surface 210A, the second surface 210B, and the side surface 210C of FIG. 2A. According to an embodiment, the first surface 210A may be formed by a front plate 202 (e.g., a glass plate or polymer plate including various coating layers) of which at least a part is substantially transparent. The second surface 210B may be formed by a rear plate 211 which is substantially opaque. The rear plate 211 may be formed, for example, of coated or colored glass, ceramic, polymer, metal (e.g., aluminum, stainless steel (STS), or magnesium), or a combination of at least two of the above-described materials. The side surface 210C may be formed by a side bezel structure (or “a side surface member”) 218 coupled to the front plate 202 and the rear plate 211 and containing metal and/or polymer. In an embodiment, the rear plate 211 and the side bezel structure 218 may be integrally formed and contain the same material (e.g., a metal material such as aluminum).

In the illustrated embodiment, the front plate 202 may be bent from the first surface 210A toward the rear plate 211 and include two seamlessly extending first areas 210D at opposite ends of a long edge of the front plate 202. In the shown embodiment (see FIG. 2B), the rear plate 211 may be bent from the second surface 210B toward the front plate 202 and include two seamlessly extending second areas 210E at opposite ends of a long edge thereof. In an embodiment, the front plate 202 (or the rear plate 211) may include only one of the first areas 210D (or the second areas 210E). In an embodiment, a part of the first areas 210D or the second areas 210E may not be included. In the embodiments, when viewed from the side surface of the electronic device 200, the side bezel structure 218 may have a first thickness (or width) at a side surface side where the above-described first areas 210D or second areas 210E are not included and may have a second thickness smaller than the first thickness at a side surface side where the above-described first areas 210D or second areas 210E are included.

According to an embodiment, the electronic device 200 may include at least one among a display 201, audio modules 203, 207, and 214, sensor modules 204, 216, and 219, camera modules 205, 212, and 213, a key input device 217, a light emitting element 206, and connector holes 208 and 209. In an embodiment, the electronic device 200 may omit at least one (e.g., the key input device 217, or the light emitting element 206) of the elements, or may additionally include another element.

The display 201 may be visually exposed (e.g., visible), for example, via a considerable portion of the front plate 202. In an embodiment, at least a part of the display 201 may be visually exposed (e.g., visible) via the first surface 210A and the front plate 202 forming the first areas 210D of the side surface 210C. In an embodiment, an edge of the display 201 may be formed to be substantially the same as a shape of an adjacent outer periphery of the front plate 202. In an embodiment (not shown), in order to expand the exposed (e.g., visible) area of the display 201, the gap between the outer periphery of the display 201 and the outer periphery of the front plate 202 may be formed to be substantially the same as each other.

In an embodiment (not shown), a recess or an opening may be formed at a part of a screen display area of the display 201, and include at least one among an audio module 214, a sensor module 204, a camera module 205, and a light emitting element 206 aligned with the recess or the opening. In an embodiment (not shown), at least one among the audio module 214, the sensor module 204, the camera module 205, a fingerprint sensor 216, and the light emitting element 206 may be included on a rear surface of the screen display area of the display 201. In an embodiment (not shown), the display 201 may be disposed to be coupled or adjacent to a touch detection circuit, a pressure sensor capable of measuring the intensity (pressure) of a touch and/or a digitizer for detecting a magnetic stylus pen. In an embodiment, at least a part of the sensor modules 204 and 219 and/or at least a part of the key input device 217 may be disposed in the first areas 210D and/or the second areas 210E.

The audio modules 203, 207, and 214 may include a microphone hole 203 and speaker holes 207 and 214. A microphone for acquiring external sound may be disposed in the microphone hole 203, and in an embodiment, a plurality of microphones may be arranged to be able to detect the direction of sound. The speaker holes 207 and 214 may include an external speaker hole 207 and a receiver hole for calls 214. In an embodiment, the speaker holes 207 and 214 and the microphone hole 203 may be implemented as a single hole, or a speaker may be included without the speaker holes 207 and 214 (e.g., a piezo speaker).

The sensor modules 204, 216, and 219 may produce electrical signals or data values corresponding to an internal operation state of the electronic device 200 or an external environmental state. The sensor modules 204, 216, and 219 may include, for example, a first sensor module 204 (e.g., a proximity sensor) and/or a second sensor module (not shown) (e.g., a fingerprint sensor) disposed on the first surface 210A of the housing 210, and/or a third sensor module 219 (e.g., an HRM sensor) and/or a fourth sensor module 216 (e.g., a fingerprint sensor) disposed on the second surface 210B of the housing 210. The fingerprint sensor may be disposed not only on the first surface 210A (e.g., the display 201) but also on the second surface 210B of the housing 210. The electronic device 200 may further include a sensor module not shown, for example, at least one among a gesture sensor, a gyro sensor, an air pressure sensor, a magnetic sensor, an acceleration sensor, a grip sensor, a color sensor, an infrared (IR) sensor, a biometric sensor, a temperature sensor, a humidity sensor, or an illuminance sensor 204.

The camera modules 205, 212, and 213 may include a first camera device 205 disposed on the first surface 210A of the electronic device 200, and a second camera device 212 and/or a flash 213 disposed on the second surface 210B. The camera devices 205 and 212 may include one or more lenses, image sensors, and/or image signal processors. The flash 213 may include, for example, a light emitting diode or a xenon lamp. In an embodiment, two or more lenses (infrared camera, wide-angle and telephoto lenses) and image sensors may be arranged on one surface of the electronic device 200.

The key input device 217 may be disposed on the side surface 210C of the housing 210. In an embodiment, the electronic device 200 may not include a part or all of the above-described key input device 217, and the key input device 217 which is not included in the electronic device may be implemented in a different form such as a soft key on the display 201. In an embodiment, the key input device may include the sensor module 216 disposed on the second surface 210B of the housing 210.

The light emitting element 206 may be disposed, for example, on the first surface 210A of the housing 210. The light emitting element 206 may provide, for example, state information of the electronic device 200 in the form of light. In an embodiment, the light emitting element 206 may provide, for example, a light source interlocked with the steps of the camera module 205. The light emitting element 206 may include, for example, an LED, an IR LED, and a xenon lamp.

The connector holes 208 and 209 may include a first connector hole 208 capable of accommodating a connector (e.g., a USB connector) for transmitting and receiving power and/or data to and from an external electronic device, and/or a second connector hole (e.g., earphone jack) 209 capable of accommodating a connector for transmitting and receiving audio signals to and from an external electronic device.

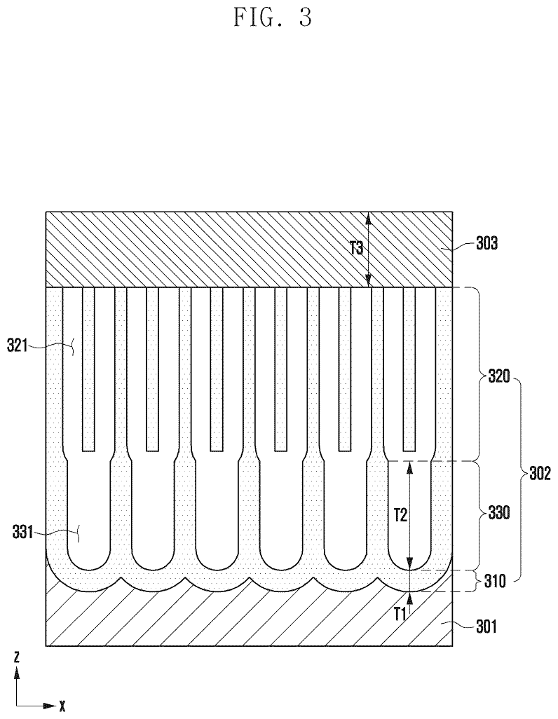

FIG. 3 is a cross-sectional view illustrating a surface of a housing of an electronic device according to various embodiments.

Referring to FIG. 3, a housing (e.g., the housing 210 of FIG. 2A and FIG. 2B) may include a base material 301 and an anodizing layer 302.

In various embodiments, the base material 301 may be aluminum or an alloy containing aluminum. Aluminum is easily processible and has a high specific strength due to low density and high strength thereof, and may thus be used for a housing of a portable electronic device. In various embodiments, the base material 301 may include an aluminum alloy containing zinc, such as a 7000 series alloy (such as 7005, 7039, and 7075 alloys). Aluminum alloy containing zinc has high precipitation hardening ability and high strength, thereby effectively protecting an electronic device from impact or penetration from the outside.

In various embodiments, an anodizing layer 302 may be formed on a surface of the base material 301. The surface on which the anodizing layer 302 is formed may be, for example, a surface facing the external appearance direction of the electronic device (this may be referred to as a “first direction”). The “first direction” may be illustrated as the z-axis direction in FIG. 3 and various drawings. However, this is a non-limiting example, and it will be clear to those skilled in the art that the anodizing layer 302 in the disclosure may be formed on the surfaces in various directions, which form the external appearance of the electronic device. The anodizing layer 302 may be a layer which contains an oxide (e.g., alumina) produced by anodizing the base material 301, and is attached to the surface of the base material 301 to protect the surface of the base material 301 from chemical damage from the outside.

In various embodiments, the anodizing layer 302 may include a first porous film 320, a second porous film 330, and a barrier layer 310. The barrier layer 310 may be a layer formed by anodizing the surface of the base material 301. The base layer 310 may be a layer which is in contact with the surface of the base material 301, protects the surface of the base material 301 from corrosion, and, when a crack is produced by the stress applied to the anodizing layer 302, arrests the propagation of the crack to prevent and/or reduce the anodizing layer 302 from being damaged and fallen off or reduce the damage and removal.

The first porous film 320 may be a layer formed by anodizing the surface of the base material 301 and located at an upper portion (e.g., the z-axis direction) of the barrier layer 310. The first porous film 320 may include porous aluminum oxide having pores (e.g., a first void 321) formed by anodizing aluminum. In various embodiments, the first porous film 320 may be an oxide layer grown before the barrier layer 310 is formed.

The second porous film 330 may be an aluminum oxide layer grown from the surface of the barrier layer 310 (e.g., the surface facing the z-axis direction) by anodizing the surface of the base material 301. The second porous film 330 may include porous aluminum oxide having pores (e.g., a second void 331) formed by anodizing aluminum. The second porous film 330 may be located between the barrier layer 310 and the first porous film 320. In various embodiments, the second porous film 330 may be a layer formed together with the barrier layer 310.

In various embodiments, a thickness T1 of the barrier layer 310 may be 10 to 150 nanometers. When the thickness T1 of the barrier layer 310 is less than 10 nanometers, the strength of the barrier layer 310 may be insufficient, and thus a crack produced by an impact applied to the housing of the electronic device may not be arrested in the barrier layer 310. Therefore, the crack may pass via the barrier layer 310 and propagate to the interface between the barrier layer 310 and the base material 301, and thus the removal or peeling of the anodizing layer 302 may occur. In addition, when the thickness T1 of the barrier layer 310 exceeds 150 nanometers, segregation of elements included in the anodizing solute may become severe as the anodizing treatment time increases, and thus adhesion between the barrier layer 310 and the base material 301 may decrease.

In various embodiments, a thickness T2 of the second porous film 330 may be 1000 to 20000 nanometers. When the thickness T2 of the second porous film 330 is less than 1000 nanometers, the thickness of the barrier layer 310 formed together with the second porous film 330 may be insufficient, and thus the resistance to cracks of the barrier layer 310 may decrease. In addition, when the thickness T2 of the second porous film 330 exceeds 20000 nanometers, deterioration of adhesion due to segregation according to the increase in anodizing treatment time and excessive coloring of the porous film by an element contained in the solute may occur.

In some embodiments, the thickness T2 of the second porous film 330 may be 1000 to 2000 nanometers. For improved surface quality, forming the second porous film 330 with a thickness T2 of 2000 nanometers or less can reduce the anodizing treatment time and improve the adhesion and gloss of the anodizing film.

In various embodiments, the diameter of the second void 331 of the second porous film 330 may be greater than the diameter of the first void 321 of the first porous film 320. In various embodiments, the first porous film 320 and the second porous film 330 may be formed by anodizing operations (e.g., a first anodizing operation (S401) and a second anodizing operation (S402) described below) having different process parameters (e.g., voltage, current, type and/or concentration of anodizing solution), and thus the first porous film 320 and the second porous film 330 may have pores having different diameters.

Referring to FIG. 3 again, in various example embodiments, the housing may include a sealing layer 303. The sealing layer 303 may be located at an upper portion (the z-axis direction) of the anodizing layer 302, and may be a layer which at least partially closes a void (e.g., the first void 321) of the anodizing layer 302. The sealing layer 303 may reduce the occurrence of cracks in the anodizing layer 302 produced from the void by closing the void, and thus appearance defects such as damage to the anodizing layer 302 due to cracks and removal from the base material 301 may be reduced.

In various embodiments, a thickness T3 of the sealing layer 303 may be 60 to 120 nanometers. When the sealing layer 303 is formed to be less than 60 nanometers, the sealing layer 303 may be formed in a state of including a void, thereby reducing the protection performance of the sealing layer 303, and when the sealing layer 303 is formed to be greater than 120 nanometers, the sealing layer 303 may be excessively crystallized, thereby reducing the protection performance of the sealing layer 303.

In various embodiments, the sealing layer 303 may include nickel (Ni) and fluorine (F). In various embodiments, the sum of nickel and fluorine components of the sealing layer 303 may be 15 to 20% by weight. In various embodiments, the ratio of nickel and fluorine components in the sealing layer 303 may be 3:2 to 2:1. The effect of the forming of the sealing layer 303 will be described in greater detail below.

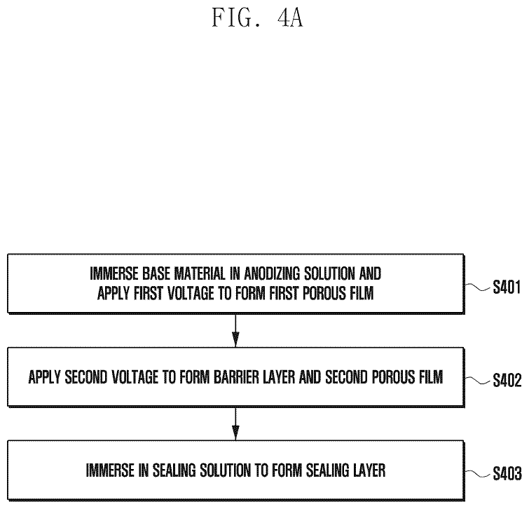

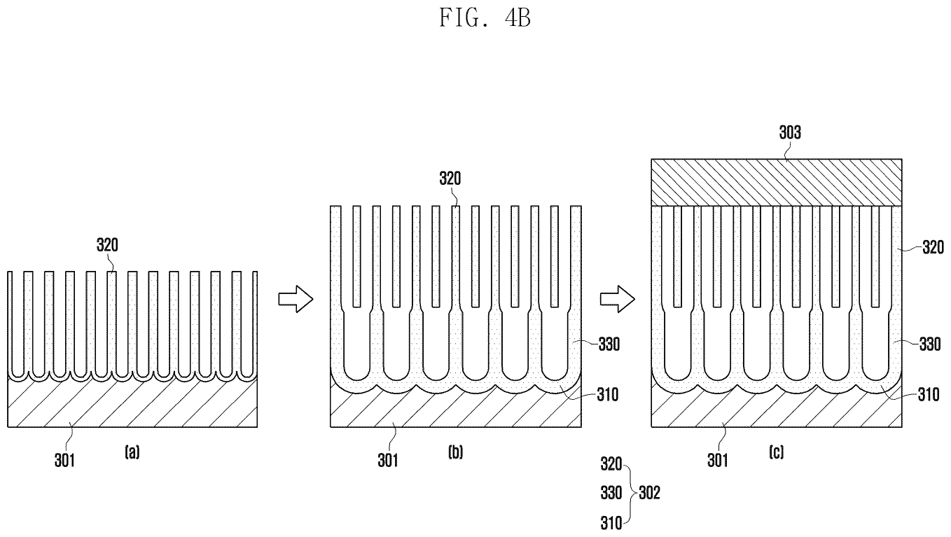

FIG. 4A is a flowchart illustrating an example method of manufacturing a housing according to various embodiments.

FIG. 4B is a diagram illustrating an example process for manufacturing a housing according to various embodiments.

Referring to FIG. 4A and FIG. 4B, a method of manufacturing a housing according to various embodiment may include a first anodizing operation (S401) and a second anodizing operation (S402).

The first anodizing operation (S401) may be an operation in which the base material 301 is immersed in an anodizing solution and then energized with a first voltage to form the first porous film 320 by the anodic oxidation on the surface of the base material 301. In various embodiments, the anodizing solution of the first anodizing operation (S401) may include sulfuric acid, oxalic acid, phosphoric acid, chromic acid, or an electrolyte solution similar thereto.

The second anodizing operation (S402) may be an operation in which the base material 301 is immersed in an anodizing solution and then energized with a second voltage to form the barrier layer 310 and the second porous film 330 by the anodic oxidation on the surface of the base material 301.

In various embodiments, the second anodizing operation (S402) may be performed in a solution including chromic acid. The purity of an oxide formed by anodic oxidation with a chromic acid in the solution may be relatively high compared to that of an oxide formed by anodic oxidation with other solutions, and thus, when the second anodizing operation (S402) is performed with a chromic acid solution, the barrier layer 310 may have the advantage of improving the hardness and adhesion. The barrier layer 310 formed by the solution including chromic acid may include chromium.

In various embodiments, the second anodizing operation (S402) may be performed in a solution including sulfuric acid. The barrier layer 310 formed by the solution including sulfuric acid may include sulfur content (such as in a form of sulfate). An oxide formed by being anodized by sulfuric acid in the solution has effect of having improved surface finish and gloss, compared to the case of being anodized in a solution not containing sulfuric acid.

Referring to FIG. 4A and FIG. 4B again, in various embodiments, a method of manufacturing a housing may include a sealing operation (S403). The sealing operation (S403) may be an operation in which the first void 321 of the first porous film 320 on the surface of the housing is sealed to improve the durability of the anodizing layer 302. The sealing operation (S403) may be an operation in which the base material 301 that has undergone the second anodizing operation (S402) is immersed in a sealing solution to form the sealing layer 303 by a chemical reaction between the anodizing layer 302 and the sealing solution on the surface of the first porous film 320. In various embodiments, the sealing solution may contain nickel (Ni) and fluorine (F). For example, the sealing solution may contain nickel fluoride, or a material such as a mixture of nickel acetate and ammonium fluoride.

In various embodiments, the immersion time for the sealing solution in the sealing operation (S403) may be 20 minutes to 50 minutes. If the immersion time is less than 20 minutes, the sealing layer 303 may not be formed to be sufficiently strong, and if the immersion time exceeds 50 minutes, the sealing layer 303 may be excessively crystallized, and thus the protection performance may deteriorate.

Although not shown, in the manufacturing method of the disclosure, it will be apparent to those skilled in the art that steps such as degreasing, etching, desmutting, and/or staining may be performed on the base material 301 and/or the anodized surface before or after performing each step.

Referring to (a) of FIG. 4B, at the time of the first anodizing operation (S401), the base material 301 may be eroded by oxidation from the surface to form the first porous film 320. Referring to (b) of FIG. 4B, the surface of the base material 301 on which the first porous film 320 is formed may be further oxidized and eroded by the second anodizing operation (S402) to form the second porous film 330 and the barrier layer 310 between the first porous film 320 and the base material 301. Referring to (c) of FIG. 4B, in a state where the second anodizing operation (S402) is completed, the sealing layer 303 may be formed on the surface of the first porous film 320.

In various embodiments, the second voltage applied at the time of the second anodizing operation (S402) may be higher than the first voltage applied at the time of the first anodizing operation (S401). Therefore, the diameter of the first void 321 of the first porous film 320 formed in the first anodizing operation (S401) may be greater than the diameter of the second void 331 of the second porous film 330 formed in the second anodizing operation (S402). The effect of producing a voltage difference in the first anodizing operation (S401) and the second anodizing operation (S402) will be described in greater detail below.

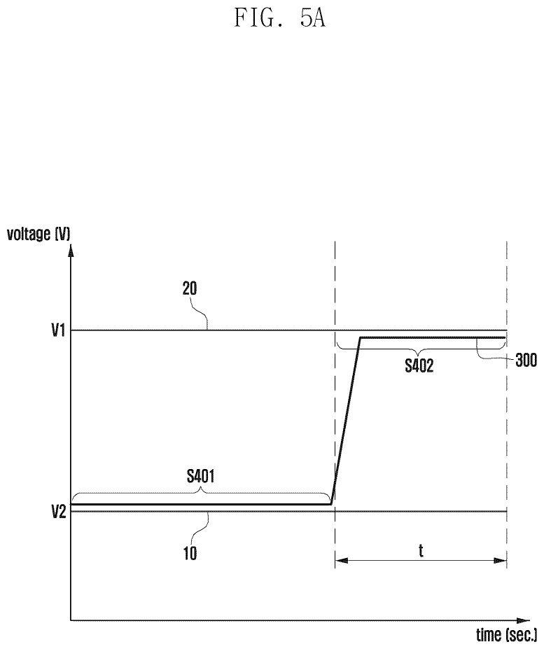

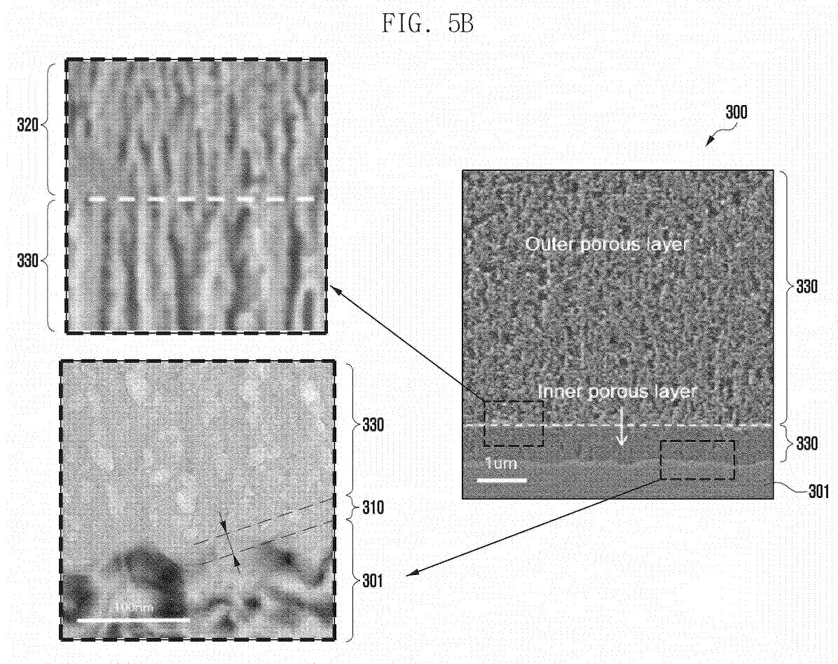

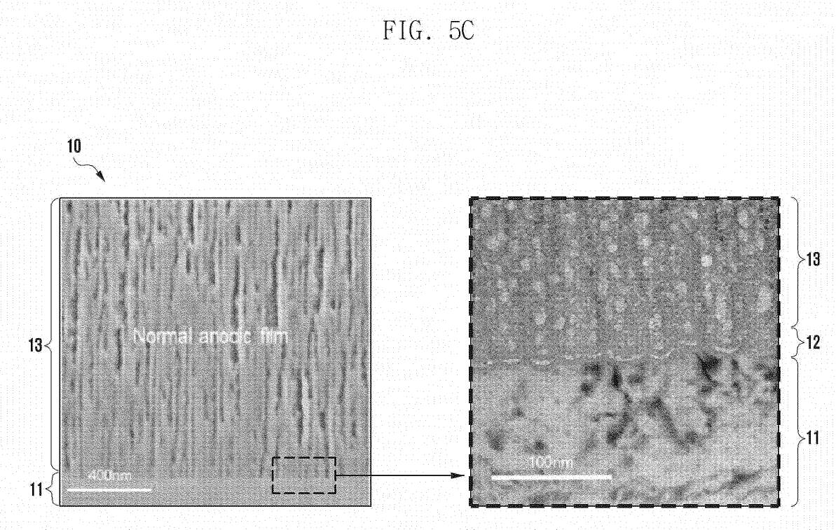

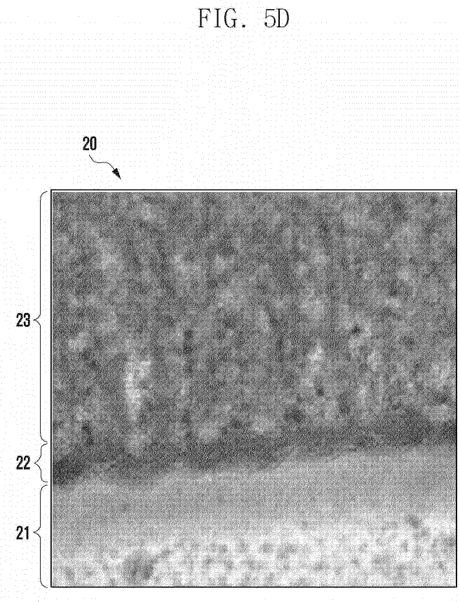

FIG. 5A is a graph showing a change in voltage over time in a method of manufacturing a housing according to comparative examples and various embodiments.

FIG. 5B is an electron micrograph showing an anodizing layer 302 and a base material 301 of a housing according to various embodiments.

FIG. 5C is an electron micrograph showing an anodizing layer 302 and a base material 301 of a housing according to a comparative example of the disclosure.

FIG. 5D is an electron micrograph showing an anodizing layer 302 and a base material 301 of a housing according to another comparative example of the disclosure.

Referring to FIG. 5A, in a method of manufacturing a housing according to various embodiments 300 of the disclosure, a first anodizing operation (S401) may be performed by applying a first voltage to a base material 301, and a second anodizing operation (S402) may be performed by applying a second voltage in a state in which the first anodizing operation (S401) is completed. The second voltage may be higher than the first voltage.

When a low voltage is applied in anodization, fine pores (e.g., first pores) having a relatively small diameter may be formed and an oxide film having a relatively slow growth rate may be formed. Such an oxide film may have excellent film quality, but at a low voltage, the thickness of the barrier layer 310 may not be sufficient, thereby being vulnerable to impact from the outside. In addition, when a high voltage is applied in anodization, coarse pores (e.g., second pores) having a relatively large diameter may be formed and an oxide film having a relatively high growth rate may be formed. Such an oxide film may be grown to have a thick barrier layer 310 due to a high voltage, but the film quality may be deteriorated due to the production of excessive bubbles due to the high voltage, excessive segregation of the anodizing solute component may occur at the interface between the barrier layer 310 and the base material 301, and thus adhesion between the barrier layer 310 and the base material 301 may be weakened.

In a method of manufacturing a housing according to an embodiment 300 of the disclosure, after forming the first porous film 320 by the first anodizing operation (S401) by low voltage, the second porous film 330 and the barrier layer 310 may be formed under the first porous film 320 by the second anodizing operation (S402) using high voltage to prevent or reduce the production of bubbles or segregation of solute components due to high voltage conduction, and thus the barrier layer 310 having the relatively thick barrier layer 310 and having improved adhesion and rigidity may be formed.

In comparison with the disclosure, a first comparative example having the anodizing layer 302 formed by low-voltage anodizing and a second comparative example having the anodizing layer 302 formed by high-voltage anodizing have been prepared, respectively, to compare with the disclosure.

Referring to FIG. 5B, it may be seen that the surface section of the housing according to the embodiment 300 of the disclosure has the first porous film 320 and the second porous film 330, and the pores of the first porous film 320 are smaller than those of the second porous film 330. In addition, the thickness of the barrier layer 310 of the second porous film 330 is measured as 55.3 nm.

Referring to FIG. 5C, it may be seen that the barrier layer 12 of the housing according to the first comparative example 10 has not been formed thickly by low-voltage anodizing and has been thinner, compared to the disclosure. Therefore, it may be seen that the crack resistance of the barrier layer 12 is not high.

Referring to FIG. 5D, it may be seen that in a housing according to the second comparative example 20, although the barrier layer 22 between the base material 21 and anodized layer 23 has been formed thickly by high voltage anodizing, segregation of solute components has occurred on the surface of the barrier layer 22 and the base material 21. Therefore, it may be seen that adhesion between the barrier layer 22 and the base material 21 is reduced.

Referring to FIG. 5A again, in various embodiments, the time t for performing the second anodizing operation (S402) may be 60 to 6000 seconds. When the second anodizing operation (S402) is performed for less than 60 seconds, the thickness of the barrier layer 310 may not be sufficient. In addition, when the second anodizing operation is performed for more than 6000 seconds, components included in the solute may be excessively segregated due to the rapid growth of the oxide film for a long time, and thus the hardness of the barrier layer 310 and the adhesion to the base material 301 may be deteriorated.

In various embodiments, the time t for performing the second anodizing operation (S402) may be 60 to 300 seconds. By performing the second anodizing operation for 300 seconds or less, the deterioration of the oxide film adhesion and gloss due to rapid oxide film growth under high voltage can be prevented and/or reduced.

The time t for performing the second anodizing operation (S402) may be 60 to 6000 seconds and he second anodizing operation (S402) may be performed in a solution including sulfuric acid. As the time for performing the second anodizing operation (S402) increases, the gloss of the oxide film may deteriorate due to the rapid growth of the second porous film 330, but the deterioration of the gloss of the oxide film may be prevented and/or reduced by the anodizing solution including sulfuric acid.

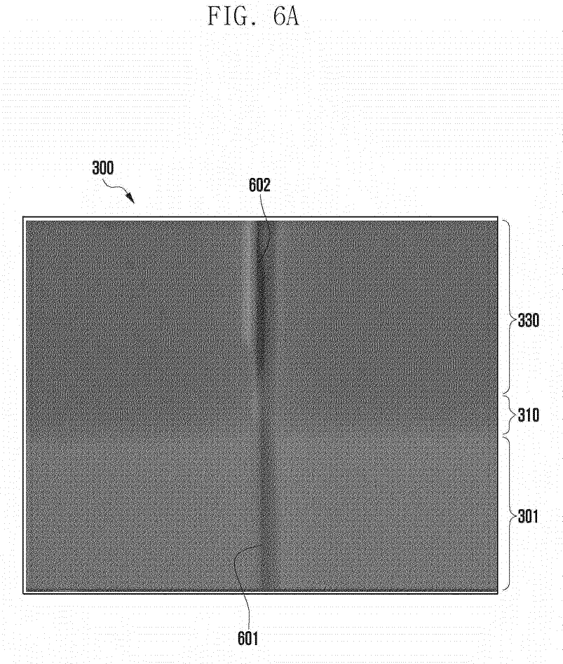

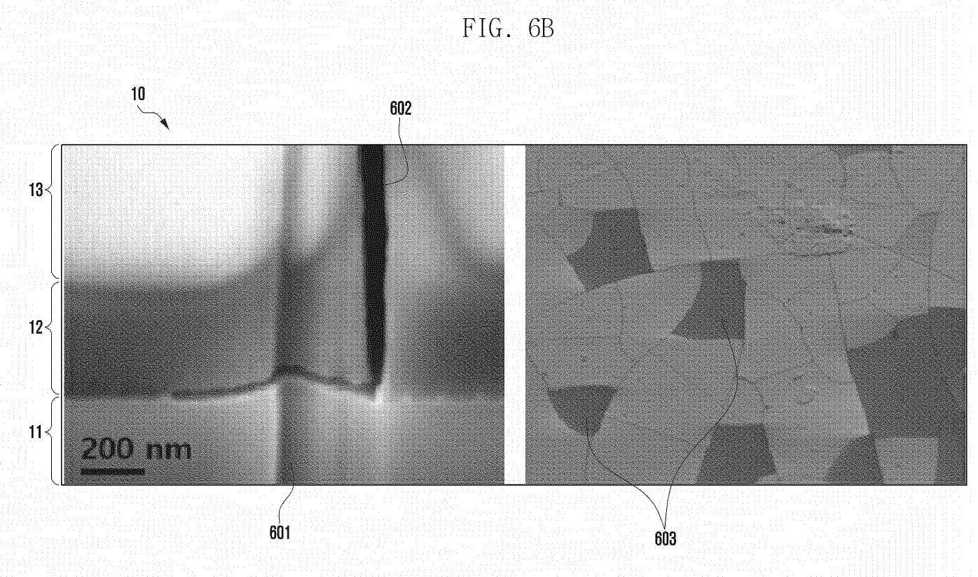

FIG. 6A is an electron micrograph showing the result of a crack propagation test with respect to a cross section of an anodizing layer 302 according to various embodiments.

FIG. 6B is an electron micrograph showing the results of a crack propagation test with respect to a cross section and a surface of an anodizing layer 302 according to a comparative example.

Referring to FIG. 6A, when processing a notch along the cross section and producing a crack 602 with respect to the anodizing layer 302 according to an embodiment 300 of the disclosure, it may be seen that the crack 602 has been arrested in the barrier layer 310 of the anodizing layer 302. Therefore, according to the disclosure, it may be seen that when the crack 602 occurs on the surface of the anodizing layer 302 due to an external impact, the crack does not propagate to the interface between the anodizing layer 302 and the base material 301, and thus the anodizing layer 302 may lower the risk of peeling-off. Referring to FIG. 6B, in the anodizing layer 12 and 13 according to the comparative example 10, it may be seen that when a notch 601 is processed along the cross section and a crack 602 is generated, the crack has not been arrested in the barrier layer 12 and has passed through the barrier layer 12 to reach the interface between the base material 11 and the barrier layer 12, and as the crack 602 has propagated along the interface, the barrier layer 12 has been peeled off 603 from the base material 11.

In order to identify the optimal composition and thickness of the sealing layer 303 of the disclosure, the durability of the sealing layer 303 has been compared after manufacturing the sealing layer 303 formed with various compositions and reaction times. The test results are shown in a table.

TABLE 1

| | Component | | | | | Polarization test current density by thickness | | |
|---|---|---|---|---|---|---|---|---|
| Division | Al | O | Ni | F | S | 30 nm | 90 nm | 150 nm |
| Comparative | 44.5% | 41.1% | 6.5% | 0% | 7.9% | 3.24 | 0.75 | 1.45 |
| example | | | | | | | | |
| Embodiment 1 | 42.8% | 39.5% | 3.9% | 5.8% | 8.1% | 3.55 | 0.81 | 1.15 |
| Embodiment 2 | 41.5% | 38.3% | 5.5% | 6.7% | 8.0% | 1.37 | 0.78 | 1.14 |
| Embodiment 3 | 39.9% | 36.8% | 9.4% | 6.1% | 7.8% | 0.85 | 0.25 | 1.02 |
| Embodiment 4 | 39.0% | 36.0% | 11.4% | 6.0% | 7.7% | 1.24 | 0.38 | 1.3 |
| Embodiment 5 | 40.0% | 34.5% | 12.9% | 5.3% | 7.5% | 1.28 | 0.72 | 4.3 |
| Embodiment 6 | 37.6% | 34.7% | 15.0% | 5.3% | 7.4% | 1.04 | 4.52 | 21.2 |

The unit of the component ratios shown in Table 1 is % by weight, and the unit of the current density is nA/cm². The polarization test measures the current passing through the sealing layer 303 per unit area when voltage is applied to the sealing layer 303. The lower the current density, the better the durability of the sealing layer 303. The comparative example shows the sealing layer 303 formed by immersion in a solution for common nickel sealing which does not contain fluorine, and embodiments 1 to 6 show the sealing layer 303 prepared to contain nickel and fluorine in different ratios. Referring to Table 1, it may be seen that embodiment 3 in which 9.4 and 6.1% by weight of nickel and fluorine are contained, respectively, so that the sum of nickel and fluorine is 15.5% by weight, and the ratio of nickel and fluorine is 1.5:1 and embodiment 4 in which 11.4% and 6.0% of nickel and fluorine are contained, respectively, so that the sum of nickel and fluorine is 17.4% and the ratio of nickel to fluorine is 1.9:1 show the lowest current density, and that examples in which the sum of nickel and fluorine exceeds 15 to 20% by weight or the ratio of nickel and fluorine exceeds 3:2 to 2:1 show the measured values of relatively high current densities.

In addition, it may be seen that in terms of the thickness of the sealing layer 303, when the thickness of the sealing layer 303 is less than 60 nanometers or exceeds 120 nanometers, the current density is relatively increased in all embodiments. Therefore, it may be seen that a thickness of 60 to 120 nanometers is the most optimal thickness for the sealing layer 303.

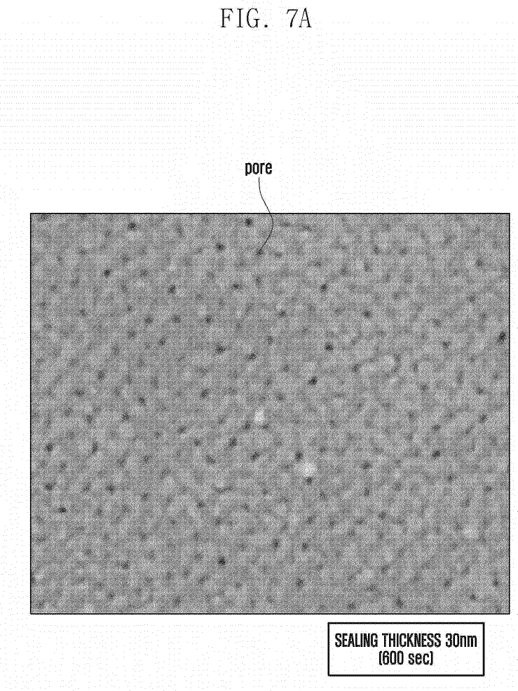

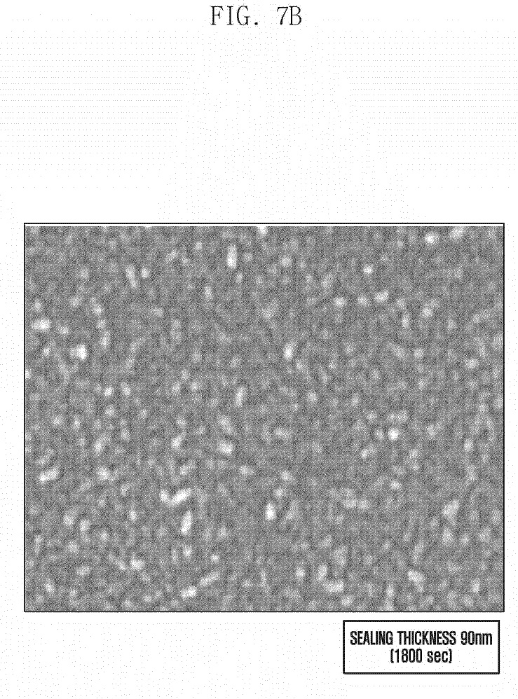

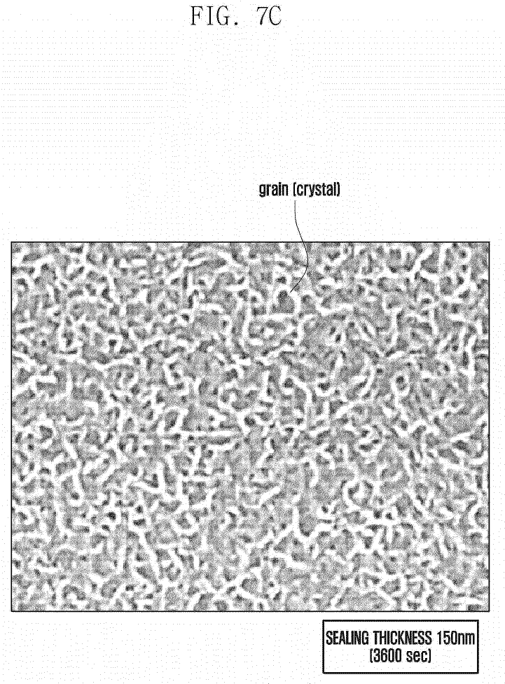

FIGS. 7A, 7B and 7C are electron micrographs showing a surface of a sealing layer 303 according to various embodiments.

FIG. 7A shows the sealing layer 303 having a thickness of 30 nanometers formed by performing the sealing operation (S403) for 10 minutes, FIG. 7B shows the sealing layer 303 formed to have a thickness of 90 nanometers by performing the sealing operation (S403) for 30 minutes, and FIG. 7C shows the sealing layer 303 formed to have a thickness of 150 nanometers by performing the sealing operation (S403) for 1 hour.

Referring to FIG. 7A, in an embodiment in which the sealing operation (S403) is performed for 10 minutes, it is identified that a plurality of pores are formed in the sealing layer 303. Therefore, it may be seen that the protection performance of the sealing layer 303 is low. In addition, referring to FIG. 7C, it may be seen that in the embodiment in which the sealing operation (S403) is performed for 1 hour, the surface of the sealing layer 303 is excessively crystallized, the grain interface acts as a weakness of the sealing layer 303, and thus the protection performance is low. When comparing FIG. 7C with FIG. 7B, it may be seen that in an embodiment in which the sealing operation (S403) is performed within a range of 20 to 50 minutes to have a thickness of 60 to 120 nanometers, the sealing layer 303 has excellent protection performance.

While the disclosure has been illustrated and described with reference to various example embodiments, it will be understood that the various example embodiments are intended to be illustrative, not limiting. It will be further understood to those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device comprising a housing,
wherein the housing comprises:
a base material comprising an aluminum alloy material;
a barrier layer comprising anodized aluminum of the base material on a surface facing a first direction of the base material, the barrier layer having a thickness of 10 to 150 nanometers;
a first porous film located in the first direction with respect to the barrier layer; and
a second porous film formed between the first porous film and the barrier layer.

2. The electronic device of claim 1, wherein a thickness of the second porous film is 1000 to 20000 nanometers.

3. The electronic device of claim 1, wherein the first porous film comprises a first void and the second porous film comprises a second void, and
wherein a diameter of the second void is greater than a diameter of the first void.

4. The electronic device of claim 1, wherein the barrier layer includes at least one of chromium or sulfur.

5. The electronic device of claim 1, comprising a sealing layer formed on a surface facing the first direction of the first porous film.

6. The electronic device of claim 5, wherein a thickness of the sealing layer is 60 to 120 nanometers.

7. The electronic device of claim 5, wherein the sealing layer includes nickel and fluorine.

8. The electronic device of claim 7, wherein a sum of nickel and fluorine included in the sealing layer is 15 to 20% by weight.

9. The electronic device of claim 7, wherein a ratio of nickel and fluorine included in the sealing layer is 3:2 to 2:1 based on weight.

10. A method of manufacturing a housing for an electronic device, the method comprising:
a first anodizing operation comprising immersing a base material in an anodizing solution and applying a first voltage to form a first porous film on a surface of the base material; and
a second anodizing operation comprising applying a second voltage to the base material on which the first anodizing operation has been performed in an anodizing solution to form a second porous film and a barrier layer on the surface between the base material and the first porous film,
wherein the second voltage is higher than the first voltage.

11. The method of claim 10, wherein the second anodizing operation is performed for 60 to 6000 seconds.

12. The method of claim 10, wherein the second anodizing operation is performed in a state of being immersed in a solution containing at least one of chromic acid or sulfuric acid.

13. The method of claim 10, further comprising a sealing operation, performed after the second anodizing operation, of immersing the base material in a sealing solution to form a sealing layer.

14. The method of claim 13, wherein the sealing solution includes nickel and fluorine.

15. The method of claim 13, wherein the sealing operation is performed for 20 to 50 minutes.

16. The method of claim 14, wherein in the sealing operation the sum of nickel and fluorine contents of the sealing layer is 15 to 20% by weight.

17. The method of claim 13, wherein in the sealing operation the ratio of nickel and fluorine contents in the sealing layer is 3:2 to 2:1 based on weight.

18. A housing of an electronic device manufactured by a method comprising:
a first anodizing operation comprising immersing a base material in an anodizing solution and applying a first voltage to form a first porous film on a surface of the base material; and
a second anodizing operation comprising applying a second voltage higher than the first voltage, to the base material on which the first anodizing operation has been performed in an anodizing solution to form a second porous film and a barrier layer on the surface between the base material and the first porous film.

19. The housing of claim 18, wherein the second anodizing operation is performed for 60 to 6000 seconds.

20. The housing of claim 18, manufactured by a method comprising a sealing operation, performed after the second anodizing operation, of immersing the base material in a sealing solution containing nickel and fluorine to form a sealing layer on a surface of the first porous film.
